(19) United States
(12) Patent Application Publication
(10) Pub. No.: US 2026/0059967 A1
(43) Pub. Date: Feb. 26, 2026

(54) DISPLAY APPARATUS

(71) Applicant: LG Display Co., Ltd., Seoul (KR)

(72) Inventors: InGoo LEE, Paju-si (KR); SeHong PARK, Paju-si (KR); Kyuhwan LEE, Paju-si (KR)

(73) Assignee: LG Display Co., Ltd., Seoul (KR)

(21) Appl. No.: 19/193,849

(22) Filed: Apr. 29, 2025

(30) Foreign Application Priority Data
Aug. 20, 2024 (KR) 10-2024-0111513

(51) Int. Cl. H10K 59/80; H10K 59/35

(52) U.S. Cl. CPC H10K 59/80515; H10K 59/353; H10K 59/878

(57) ABSTRACT

Disclosed is a display apparatus including: a substrate including a plurality of pixels having a plurality of sub-pixels; a pattern portion disposed on the substrate and concavely formed in a non-light emission area between the plurality of the sub-pixels; and a reflective portion disposed on the pattern portion, wherein each of the plurality of subpixels includes a pixel electrode disposed to be spaced apart from the reflective portion, and the pixel electrode includes a main body and a plurality of protrusions protruding from the main body toward the reflective portion. This configuration enhances the reflective properties in the non-light emission regions, helping to improve overall display efficiency, brightness uniformity, and image clarity.

### CROSS-REFERENCE TO RELATED APPLICATIONS

This application claims the benefit of the Korean Patent Applications No. 10-2024-0111513 filed on Aug. 20, 2024, which are hereby incorporated by reference as if fully set forth herein.

### BACKGROUND

### Technical Field

The present disclosure relates to a display apparatus displaying images.

### Description of the Related Art

Since an organic light emitting display apparatus has a high response speed and low power consumption and self-emits light without requiring a separate light source unlike a liquid crystal display apparatus, there is no problem in a viewing angle and thus the organic light emitting display apparatus has received attention as a next-generation flat panel display apparatus.

Such a display apparatus displays an image through light emission of a light emitting element layer that includes a light emitting layer interposed between two electrodes.

Meanwhile, light extraction efficiency of the display apparatus is reduced as some of light emitted from the light emitting element layer is not emitted to the outside due to total reflection on the interface between multiple layers inside a display panel.

### BRIEF SUMMARY

An aspect of the present disclosure is directed to providing a display apparatus in which a light extraction efficiency of light emitted from a light emitting element layer may be improved.

Further, an aspect of the present disclosure is directed to providing a display apparatus in which overall power consumption may be reduced through light extraction from a non-light emission area.

Further, an aspect of the present disclosure is directed to providing a display apparatus in which deviation in light extraction efficiency may be reduced.

The problems to be solved by the examples of the present disclosure are not limited to those mentioned above, and other problems not mentioned will be apparent to one of ordinary skill in the art to which the technical spirits of the present disclosure belong from the following description.

A display apparatus comprising: a substrate including a plurality of pixels having a plurality of sub-pixels; a pattern portion disposed on the substrate and concavely formed in a non-light emission area between the plurality of the sub-pixels; and a reflective portion disposed on the pattern portion, wherein each of the plurality of subpixels includes a pixel electrode disposed to be spaced apart from the reflective portion, and the pixel electrode includes a main body and a plurality of protrusions protruding from the main body toward the reflective portion.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a schematic plan view of a display apparatus according to one embodiment of the present disclosure.

FIG. 2 is a schematic plan view of one pixel illustrated in FIG. 1.

FIG. 3 is a schematic cross-sectional view of the line I-I′ shown in FIG. 2.

FIG. 4 is a schematic cross-sectional view of the line II-II′ shown in FIG. 2.

FIG. 5 is a schematic plan view showing a pixel electrode and a reflective portion of one sub-pixel shown in FIG. 2.

FIG. 6A is a graph showing light extraction efficiency at D1 in FIG. 5.

FIG. 6B is a graph showing light extraction efficiency at D2 in FIG. 5.

FIG. 6C is a graph showing light extraction efficiency at D3 in FIG. 5.

FIG. 6D is a graph showing the light extraction efficiency of a display apparatus according to one embodiment of the present disclosure and the light extraction efficiency of a display apparatus according to a comparative example.

FIG. 7 is a schematic plan view showing a plurality of pixels of a display apparatus according to one embodiment of the present disclosure.

FIG. 8 is a schematic plan view showing a pixel electrode and a reflective portion of one sub-pixel of a display apparatus according to another embodiment of the present disclosure.

FIG. 9 is a schematic image illustrating light extraction characteristics of a display apparatus according to another embodiment of the present disclosure.

### DETAILED DESCRIPTION

Reference will now be made in detail to the embodiments of the present disclosure, examples of which are illustrated in the accompanying drawings. Wherever possible, the same reference numbers will be used throughout the drawings to refer to the same or like parts. Advantages and features of the present disclosure, and implementation methods thereof will be clarified through following embodiments described with reference to the accompanying drawings.

The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout. In the following description, when the detailed description of the relevant known function or configuration is determined to unnecessarily obscure the important point of the present disclosure, the detailed description will be omitted.

In a case where ‘comprise’, ‘have’, and ‘include’ described in the present specification are used, another part may be added unless ‘only˜’ is used. The terms of a singular form may include plural forms unless referred to the contrary.

In construing an element, the element is construed as including an error range although there is no explicit description.

In describing a position relationship, for example, when a position relation between two parts is described as ‘on˜’, ‘over˜’, ‘under˜’, and ‘next˜’, one or more other parts may be disposed between the two parts unless ‘just’ or ‘direct’ is used.

In describing a temporal relationship, for example, when the temporal order is described as “after,” “subsequent,” “next,” and “before,” a case which is not continuous may be included, unless “just”or “direct”is used.

As used herein, the terms “connected” and “coupled” are intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled”should be interpreted in the same manner.

It will be understood that, although the terms “first,” “second,” etc., may be used herein to describe various elements, these elements should not be limited by these terms.

These terms are only used to distinguish one element from another. For example, a first element could be termed a second element, and, similarly, a second element could be termed a first element, without departing from the scope of the present disclosure.

“X-axis direction”, “Y-axis direction” and “Z-axis direction” should not be construed by a geometric relation only of a mutual vertical relation and may have broader directionality within the range that elements of the present disclosure may act functionally.

The term “at least one” should be understood as including any and all combinations of one or more of the associated listed items. For example, the meaning of “at least one of a first item, a second item and a third item” denotes the combination of all items proposed from two or more of the first item, the second item and the third item as well as the first item, the second item or the third item.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in co-dependent relationship.

Hereinafter, the preferred embodiments of the present disclosure will be described in detail with reference to the accompanying drawings.

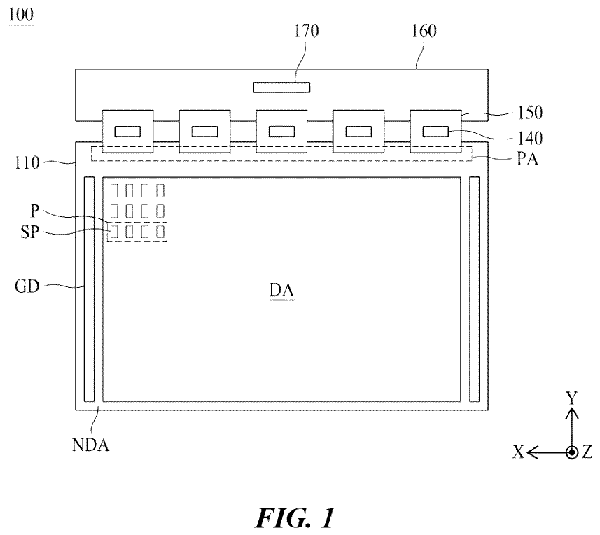

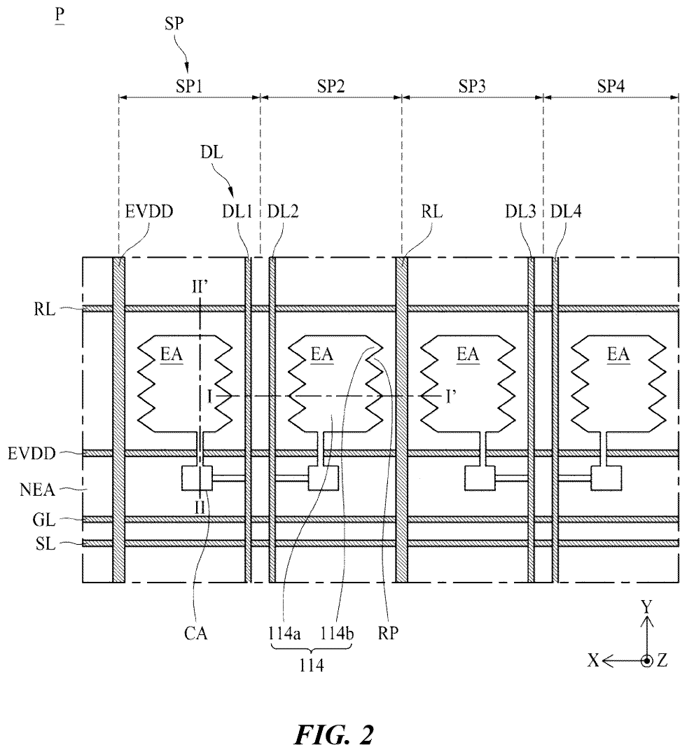

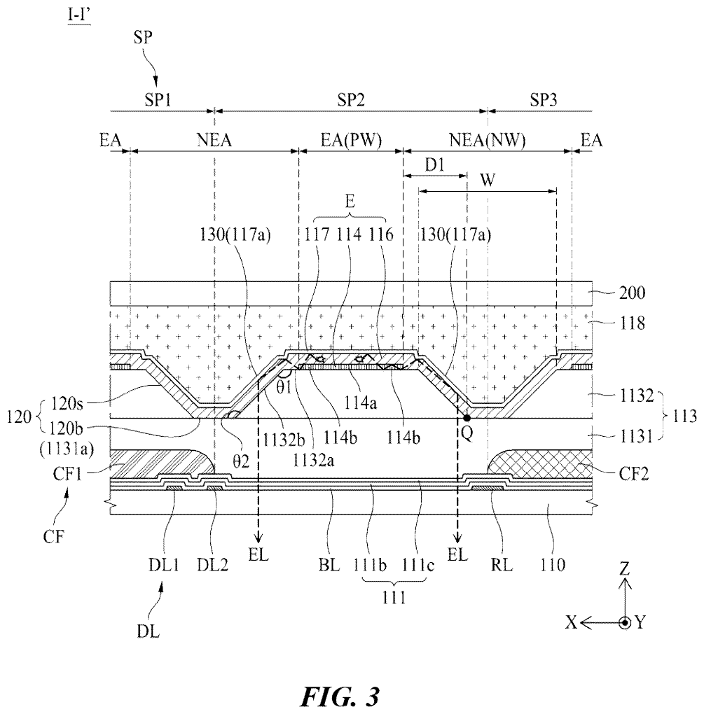

FIG. 1 is a schematic plan view of a display apparatus according to one embodiment of the present disclosure, FIG. 2 is a schematic plan view of one pixel illustrated in FIG. 1, and FIG. 3 is a schematic cross-sectional view of the line I-I′ shown in FIG. 2.

Referring now to FIGS. 1 to 3, a display apparatus 100 according to one embodiment of the present disclosure may include a substrate 110 including a plurality of pixels including a plurality of sub-pixels SPs, a pattern portion 120 disposed on the substrate 110 and concavely formed in a non-light emission area NEA between the plurality of sub-pixels SPs, and a reflective portion 130 disposed on the pattern portion 120.

Each of the plurality of subpixels SP may include a pixel electrode 114 disposed to be spaced apart from the reflective portion 130. The pixel electrode 114 according to one example may include a main body 114a and a plurality of protrusions 114b. The plurality of protrusions 114b may protrude from the main body 114a toward the reflective portion 130.

For example, each of the plurality of protrusions 114b may protrude from the main body 114a toward the reflective portion 130 in a first direction (X-axis direction). Additionally, the plurality of protrusions 114b may be arranged adjacent to each other in a second direction (Y-axis direction) that intersects the first direction (X-axis direction). Accordingly, each of the plurality of protrusions 114b may be arranged to face the reflective portion 130. Therefore, as shown in FIG. 2, each of both sides of the pixel electrode 114 on plan view may be provided with a structure having an uneven shape (or a wave shape).

The first direction (X-axis direction) may be a horizontal direction with respect to FIG. 2. The horizontal direction may be a direction in which the gate lines GL are arranged to be long. The second direction (Y-axis direction) intersects the first direction (X-axis direction) and may be a vertical direction with respect to FIG. 2. The vertical direction may be a direction in which the data lines DL are arranged long. The third direction (Z-axis direction) is a direction that intersects each of the first direction (X-axis direction) and the second direction (Y-axis direction) and may be the thickness direction of the display apparatus 100.

In the display apparatus 100 according to one embodiment of the present disclosure, each of the plurality of protrusions 114b is arranged to face the reflective portion 130, so that a deviation in light extraction efficiency depending on the distance (or separation distance) between the pixel electrode 114 and the reflective portion 130 can be alleviated. Here, the light extraction efficiency deviation means the standard deviation of the light extraction efficiency, and the standard deviation may mean the degree of dispersion or dispersion of the statistical data group of the light extraction efficiency through repeated experiments for various separation distances between the pixel electrode 114 and the reflective portion 130.

In the case of a general display apparatus, both sides of the pixel electrode facing the reflective portion on a plan view are provided in a straight line with no uneven shape, so if a process deviation occurs when forming the pixel electrode, the distance between one side of the pixel electrode and the reflective portion may differ from the distance between the other side of the pixel electrode and the reflective portion. In this case, a large difference may occur between the light extraction efficiency of the reflective portion facing one side of the pixel electrode and the light extraction efficiency of the reflective portion facing the other side of the pixel electrode. In particular, if the distance between the pixel electrode and the reflective portion exceeds a certain range (or design value), the light extraction efficiency drastically decreases, causing a problem of worsening light extraction efficiency deviation.

In contrast, in the display apparatus 100 according to one embodiment of the present disclosure, the pixel electrode 114 is provided on a plan view to include a main body 114a and a plurality of protrusions 114b that protrude from the main body 114a toward the reflective portion 130 and are disposed to face the reflective portion 130, so that each of both sides of the pixel electrode 114 has an uneven shape (or wave shape) no straight shape. Therefore, in the display apparatus 100 according to one embodiment of the present disclosure, even if a process deviation occurs when forming the pixel electrode 114, the distance away from the reflective portion 130 due to the plurality of protrusions 114b can be limited to a certain range (or design value), and as a result, the deviation in light extraction efficiency can be reduced or alleviated.

Hereinafter, reference to FIGS. 1 and 2, the display apparatus 100 according to an embodiment of the present specification will be described in more detail.

Referring to FIGS. 1 and 2, the display apparatus 100 according to one embodiment of the present disclosure may include a display panel having a gate driver GD, a source drive integrated circuit (hereinafter, referred to as “IC”) 140, a flexible film 150, a circuit board 160, and a timing controller 170.

The display panel may include a substrate 110 and an opposite substrate 200 (shown in FIG. 3).

The substrate 110 may include a thin film transistor, and may be a transistor array substrate, a lower substrate, a base substrate, or a first substrate. The substrate 110 may be a transparent glass substrate or a transparent plastic substrate. The substrate 110 may include a display area DA and a non-display area NDA.

The display area DA is an area where an image is displayed, and may be a pixel array area, an active area, a pixel array unit, a display unit, or a screen. For example, the display area DA may be disposed at a central portion of the display panel. The display area DA may include a plurality of pixels P.

The opposite substrate 200 may encapsulate (or seal) the display area DA disposed on the substrate 110. For example, the opposite substrate 200 may be bonded to the substrate 110 via an adhesive member (or clear glue). The opposite substrate 200 may be an upper substrate, a second substrate, or an encapsulation substrate. The opposite substrate 200 may comprise a metal layer that is magnetic, such as Invar, SUS, or the like. Alternatively, the opposite substrate 200 may be composed of multiple layers, such as a metal layer for good heat dissipation, such as Aluminum, an organic adhesive layer for adhesion, and an organic protective layer that is thicker than the metal layer for improved encapsulating performance.

The gate driver GD supplies gate signals to the gate lines in accordance with the gate control signal input from the timing controller 180. The gate driver GD may be formed on one side of the light emission area EA or in the non-light emission area NEA outside both sides of the light emission area EA in a gate driver in panel (GIP) method, as shown in FIG. 1.

The non-display area NDA is an area on which an image is not displayed, and may be a peripheral area, a signal supply area, an inactive area or a bezel area. The non-display area NDA may be configured to be in the vicinity of the display area DA. That is, the non-display area NDA may be disposed to surround the display area DA.

A pad area PA may be disposed in the non-display area NDA. The pad area PA may supply a power source and/or a signal for displaying an image to the pixel P provided in the display area DA. Referring to FIG. 1, the pad area PA may be provided above the display area DA.

The source drive IC 140 receives digital video data and a source control signal from the timing controller 170. The source drive IC 140 converts the digital video data into analog data voltages in accordance with the source control signal and supplies the analog data voltages to the data lines. When the source drive IC 140 is manufactured as a driving chip, the source drive IC 140 may be packaged in the flexible film 150 in a chip on film (COF) method or a chip on plastic (COP) method.

Pads, such as data pads, may be formed in the non-display area NDA of the display panel. Lines connecting the pads with the source drive IC 140 and lines connecting the pads with lines of the circuit board 160 may be formed in the flexible film 150. The flexible film 150 may be attached onto the pads by using an anisotropic conducting film, whereby the pads may be connected with the lines of the flexible film 150.

The circuit board 160 may be attached to the flexible films 150. A plurality of circuits implemented as driving chips may be packaged in the circuit board 160. For example, the timing controller 170 may be packaged in the circuit board 160. The circuit board 160 may be a printed circuit board or a flexible printed circuit board.

The timing controller 170 receives the digital video data and a timing signal from an external system board through a cable of the circuit board 160. The timing controller 170 generates a gate control signal for controlling an operation timing of the gate driver GD and a source control signal for controlling the source drive ICs 140 based on the timing signal. The timing controller 170 supplies the gate control signal to the gate driver GD, and supplies the source control signal to the source drive ICs 140.

Referring to FIGS. 2 and 3, the substrate 110 according to an example may include the light emission area EA and the non-light emission area NEA.

The light emission area EA may mean an area from which light is emitted. A light emitting element layer E, which includes a pixel electrode 114, an organic light emitting layer 116 and a reflective electrode 117, may be disposed in the light emission area EA. When an electric field is formed between the pixel electrode 114 and the reflective electrode 117, the organic light emitting layer 116 in the light emission area EA may emit light.

As shown in FIG. 3, an optical path of a portion of the light emitted by the organic light emitting layer 116 may be formed toward an adjacent sub-pixel (or non-emitting sub-pixel) through total reflection at the interface between the overcoat layer 113 and the pixel electrode 114, and the interface between the pixel electrode 114 and the organic light emitting layer 116. The display apparatus 100 according to one embodiment of the present disclosure may have the reflective portion 130 disposed between the sub-pixels SPs, thereby reflecting light toward adjacent subpixels and emitting it in the form of reflected light EL toward the non-light emission area NEA. However, embodiments of the present disclosure are not limited thereto, the reflected light EL reflected by the reflective portion 130 may be emitted toward the subpixel that emits light.

Accordingly, the display apparatus 100 according to one embodiment of the present disclosure extracts light to an adjacent subpixel by the reflective portion 130, so that light extraction can be performed even in the non-light emission area NEA. Therefore, the display apparatus 100 according to one embodiment of the present disclosure compared to a display apparatus without a reflective portion, the luminous efficiency can be the same or improved even at low power, thereby reducing overall power consumption.

In addition, the display apparatus 100 according to an embodiment of the present disclosure can prevent light from being emitted to adjacent subpixels SP due to the reflective portion 130 disposed between the subpixels SP, thereby preventing color mixing.

As a result, the display apparatus 100 according to an embodiment of the present disclosure can improve overall light efficiency while preventing color mixing with adjacent subpixels (or adjacent subpixels that do not emit light) through the reflective portion 130 concavely formed on the pattern portion 120 of the non-light emission area NEA.

Referring back to FIG. 2, the light emission area EA according to an example may include gate lines, data lines, pixel driving power lines, and a plurality of pixels P. Each of the plurality of pixels P may include a plurality of subpixels SP that may be defined by the gate lines and the data lines.

At least four subpixels, which are provided to emit light of different colors and disposed to be adjacent to one another, among the plurality of subpixels SP may constitute one pixel P (or unit pixel). One pixel P may include, but is not limited to, a red subpixel, a white subpixel, a blue subpixel and a green subpixel. One pixel P may include three subpixels SP provided to emit light of different colors and disposed to be adjacent to one another. For example, one pixel P may include a red subpixel, a green subpixel and a blue subpixel.

Each of the plurality of subpixels SP includes a thin film transistor and a light emitting element layer E connected to the thin film transistor. Each of the plurality of subpixels may include a light emitting layer (or an organic light emitting layer) interposed between the pixel electrode and the reflective electrode.

The light emitting layers disposed in each of the plurality of sub-pixels SP may emit white light in common. Since the light emitting layer of each of the plurality of sub-pixels SP emits white light in common, each of the red sub-pixel, the green sub-pixel, and the blue sub-pixel may include a color filter CF (or wavelength conversion member CF) that converts the white light to the respective colored light. In this case, the white sub-pixel may not comprise a color filter.

In the display apparatus 100 according to one embodiment of the present disclosure, the area with the red color filter may be a red sub-pixel or a first sub-pixel, the area without the color filter may be a white sub-pixel or a second sub-pixel, the area with the blue color filter may be a blue sub-pixel or a third sub-pixel, and the area with the green color filter may be a green sub-pixel or a fourth sub-pixel.

Each of the subpixels SP supplies a current of predetermined magnitude to the organic light emitting element in accordance with a data voltage of the data line when a gate signal is input from the gate line by using the thin film transistor. For this reason, the light emitting layer of each of the subpixels may emit light with a predetermined brightness in accordance with the current of predetermined magnitude.

The plurality of subpixels SP according to one example may be disposed to be adjacent to each other in a first direction (X-axis direction).

The plurality of subpixels SP may include a first subpixel SP1, a second subpixel SP2, a third subpixel SP3 and a fourth subpixel SP4 arranged adjacent to each other in the first direction (X-axis direction). The first subpixel SP1 may be configured to emit a light of first color, and the second subpixel SP2 may be configured to emit a light of second color different from the first color. Additionally, the third subpixel SP3 may be provided to emit a light of third color different from the first and second colors, and the fourth subpixel SP4 may be provided to emit a light of fourth color different from the first to third colors. Accordingly, the first to fourth subpixels SP1, SP2, SP3, and SP4 may be provided to emit light of different colors.

For example, the first subpixel SP1 may be a red subpixel, the second subpixel SP2 may be a white subpixel, the third subpixel SP3 may be a blue subpixel and the fourth subpixel SP4 may be a green subpixel, but is not limited thereto. However, the arrangement order of the first subpixel SP1, the second subpixel SP2, the third subpixel SP3 and the fourth subpixel SP4 may be changed.

Each of the first to fourth subpixels SP1 to SP4 may include a light emission area EA and a circuit area CA. The light emission area EA may be disposed at one side (or an upper side) of a subpixel area, and the circuit area CA may be disposed at the other side (or a lower side) of the subpixel area. For example, the circuit area CA may be disposed at one side (or the lower side) of the light emission area EA based on the second direction (Y-axis direction). The light emission area EA of each of the first to fourth sub-pixels SP1 to SP4 may have the same size (or area) from each other. In this case, the manufacturing process of the display apparatus 100 according to one embodiment of the present disclosure may be easy. However, it is not limited to this, and in the display apparatus 100 according to one embodiment of the present disclosure, the light emission area EA of each of the first to fourth subpixels SP1 to SP4 may be provided to have different sizes (or areas) depending on the light emission efficiency of each subpixel.

The first to fourth subpixels SP1 to SP4 may be disposed to be adjacent to one another along the first direction (X-axis direction). For example, two data lines DL extended long along the second direction (Y-axis direction) may be disposed in parallel with each other between the first subpixel SP1 and the second subpixel SP2 and between the third subpixel SP3 and the fourth subpixel SP4. A pixel power line EVDD (or branch wiring of the pixel power line) extended along the first direction (X-axis direction) may be disposed between the light emission area EA and the circuit area CA of each of the first to fourth subpixels SP1 to SP4. The gate line GL and a sensing line SL may be disposed below the circuit area CA. The pixel power line EVDD (shown in FIG. 2) extended along the second direction (Y-axis direction) may be disposed at one side of the first subpixel SP1 or the fourth subpixel SP4. A reference line RL extended long along the second direction (Y-axis direction) may be disposed between the second subpixel SP2 and the third subpixel SP3. The reference line RL may be used as a sensing line for sensing a change of characteristics of a driving thin film transistor and/or a change of characteristics of the light emitting element layer, which is disposed in the circuit area, from the outside in a sensing driving mode of the pixel P. In one example, the data lines DL are for supplying data signals to each of the plurality of the sub-pixels SP to drive each of the plurality of the sub-pixels SP. For example, the data lines DL may include a first data line DL1 for driving a first sub-pixel SP1, a second data line DL2 for driving a second sub-pixel SP2, a third data line DL3 for driving a third sub-pixel SP3, and a fourth data line DL4 for driving a fourth sub-pixel SP4.

In the display apparatus 100 according to one embodiment of the present disclosure, the data lines may be disposed not to overlap the light emission area EA. For example, as shown in FIG. 3, the second data line DL2 may be arranged such that it does not overlap the light emission area EA. Thus, in the display apparatus 100 according to one embodiment of the present disclosure, the second data line DL2 does not overlap (or is not interfered with) light emitted from the light emission area EA, thus a decrease in light extraction efficiency may be prevented. The first data line DL1, the third data line DL3, and the fourth data line DL4, like the second data line DL2, may be disposed in the non-light emission area NEA of the corresponding sub-pixel no to be overlapped the light emission area EA of the corresponding sub-pixel in the third direction (Z-axis direction). Thus, in the display apparatus 100 according to one embodiment of the present disclosure, the data lines DL1, DL2, DL3, DL4 may have a structural feature that do not overlap the light emission area EA but overlap the non-light emission area NEA.

On the other hand, each of the pixel power line EVDD and the reference line RL may be disposed in the non-light emission area NEA so as not to obscure (or interfere with) light emitted from the light emission area EA, such as the data lines described above.

In the display apparatus 100 according to one embodiment of the present disclosure, each of the plurality of the sub-pixels SP may include the light emission area EA disposed adjacent to the non-light emission area NEA. As shown in FIG. 3, the reflective portion 130 may be spaced apart from the light emission area EA. This is because if the reflective portion 130 is not spaced apart from the light emission area and is disposed adjacent to the light emission area or overlapped with the light emission area, the light emitted from the light emission area EA is difficult to be reflected by the reflective portion 130.

Thus, in the display apparatus 100 according to one embodiment of the present disclosure, the reflective portion 130 is spaced apart from the light emission area EA, such that light directed to an adjacent sub-pixel (e.g., the third sub-pixel SP3) among the light emitted from the light emission area EA may be reflected by the reflective portion 130, thereby improving light extraction efficiency.

As shown in FIG. 3, the light emission area EA is an area defined by the pixel electrode 114 disposed on the overcoat layer 113, so the reflective portion 130 may be spaced apart from the pixel electrode 114 in the first direction (X-axis direction).

Referring to FIG. 3, in the display apparatus 100 according to one embodiment of the present disclosure, the reflective portion 130 may be partially disposed closer to the substrate 110 than the pixel electrode 114. Here, a portion of the reflective portion 130 disposed closer to the substrate 110 than the pixel electrode 114 may mean a portion of the reflective portion 130 below the pixel electrode 114 among the reflective portion 130 on the inclined surface 120s of the pattern portion 120. As shown in FIG. 3, the portion of the reflective portion 130 may occupy most of the reflective portion 130. Therefore, in the display apparatus 100 according to one embodiment of the present disclosure, the reflective portion 130 is partially disposed closer to the substrate 110 than the pixel electrode 114, so that most of the light directed toward the adjacent subpixel (or subpixels that do not emit light) can be reflected through total reflection at the interface between the overcoat layer 113 and the pixel electrode 114 and the interface between the pixel electrode 114 and the organic light emitting layer 116. As a result, the light extraction efficiency of the display apparatus 100 according to one embodiment of the present disclosure can be improved.

Meanwhile, the pattern portion 120 according to an example may be concavely formed in the non-light emission area NEA. For example, the pattern portion 120 may be concavely formed in the overcoat layer 113 (shown in FIG. 3) on the substrate 110. The overcoat layer 113 according to one example may include a first layer 1131 and a second layer 1132 disposed on the first layer 1131. The pattern portion 120 may be formed by patterning and removing a portion of the second layer 1132 included in the overcoat layer 113. Accordingly, the pattern portion 120 may be expressed in terms of groove, slit, trench, overcoat layer slit, and overcoat layer trench.

The second layer 1132 of the overcoat layer 113 according to one example may include an upper surface 1132a and an inclined surface 1132b. The upper surface 1132a of the second layer 1132 may be a surface that partially contacts the pixel electrode 114 (or the bottom surface of the pixel electrode 114). The inclined surface 1132b of the second layer 1132 is connected to the upper surface 1132a and may be an inclined surface. The upper surface 1132a of the second layer 1132 according to one example may form an obtuse angle θ1 with the inclined surface 1132b. Since the upper surface 1132a and the inclined surface 1132b of the second layer 1132 are provided to form an obtuse angle θ1, the reflective electrode 117 disposed on the second layer 1132 can be provided to have a gentle slope along the profile of the second layer 1132. Accordingly, in the display apparatus 100 according to one embodiment of the present disclosure, disconnection of the reflective electrode 117 can be prevented.

As shown in FIG. 3, the second layer 1132 may be provided to have a predetermined thickness. Accordingly, the second layer 1132 may be partially patterned to provide a pattern portion 120 having a gentle slope, and the reflective electrode 117 disposed on the pattern portion 120 may have a gentle slope along the profile of the second layer 1132. Alternatively, the reflective portion 130 on the pattern portion 120 may have a concave shape.

The pattern portion 120 may be arranged to be spaced apart from the light emission area EA. The pattern portion 120 according to one example may be spaced apart from a portion of the light emission area EA in the form of a slit or trench. For example, with reference to FIG. 3, the pattern portion 120 may be disposed on both sides of the pixel electrode 114. Since a plurality of protrusions 114b are disposed on each of both sides of the pixel electrode 114, the pattern portion 120 may be arranged to face the plurality of protrusions 114b. Accordingly, the reflective portion 130 disposed on the pattern portion 120 may also be arranged to face the plurality of protrusions 114b. Here, the fact that the reflective portion 130 and the plurality of protrusions 114b are arranged to face each other may mean that there is no structure that changes the light path between the reflective portion 130 and the plurality of protrusions 114b.

As shown in FIG. 3, the width W of the pattern portion 120 may be formed to decrease in the direction from the reflective portion 130 toward the substrate 110 (or from the pixel electrode 114 toward the substrate 110). Accordingly, the reflective portion 130 on the pattern portion 120 may also be concavely formed along the profile of the pattern portion 120, and because of this, the reflective portion 130 may reflect light emitted from the light emission area EA toward an adjacent subpixel to the light emission area EA or the non-light emission area NEA of the subpixel SP.

The pattern portion 120 according to an example may include an inclined surface 120s and a bottom surface 120b. The bottom surface 120b of the pattern portion 120 is disposed parallel to the top surface of the substrate 110. The inclined surface 120s of the pattern portion 120 is a surface disposed inclined with respect to the bottom surface 120b of the pattern portion 120. For example, the inclined surface 120s of the pattern portion 120 and the bottom surface 120b of the pattern portion 120 may form an obtuse angle.

As shown in FIG. 3, the bottom surface 120b of the pattern portion 120 is a portion where the first layer 1131 of the overcoat layer 113 is exposed without being covered by the second layer 1132, so it may be indicated as an upper surface 1131a of the first layer 1131. Since the inclined surface 120s of the pattern portion 120 is a surface formed by patterning the second layer 1132 of the overcoat layer 113, it may be indicated as an inclined surface 1132b of the second layer 1132. Therefore, as shown in FIG. 3, the inclined surface 1132b of the second layer 1132 may form an obtuse angle θ2 with the upper surface 1131a of the first layer 1131. The inclined surface 1132b of the second layer 1132 and the upper surface 1131a of the first layer 1131 are provided to form an obtuse angle θ2, so that the reflective portion 130 can be disposed at an obtuse angle with respect to the bottom surface 120b of the pattern portion 120. Accordingly, the reflective portion 130 may reflect light directed toward the adjacent subpixel SP toward the subpixel SP (or the substrate 110) that emits light.

As a result, in the display apparatus 100 according to one embodiment of the present disclosure, the second layer 1132 disposed on the first layer 1131 is provided in a trapezoidal shape, as shown in FIG. 3, so that the reflective portion 130 disposed on the pattern portion 120 can be provided in a concave shape. Accordingly, in the display apparatus 100 according to one embodiment of the present disclosure, light extraction efficiency can be improved due to the concave shape of the reflective portion 130 disposed on the pattern portion 120, and color mixing between subpixels can also be prevented.

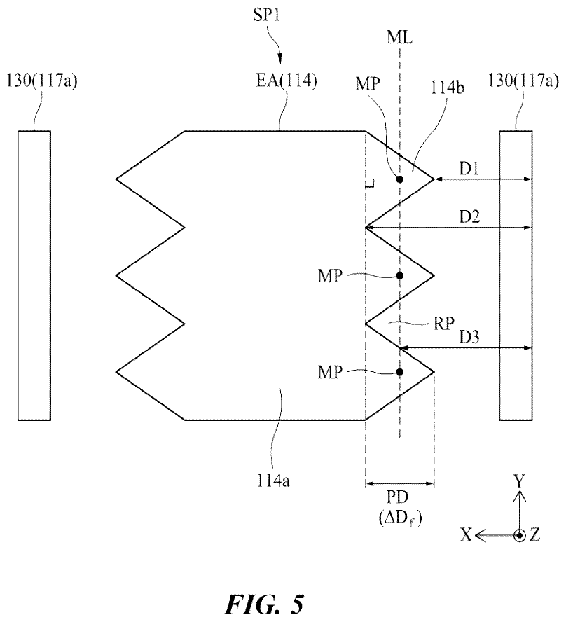

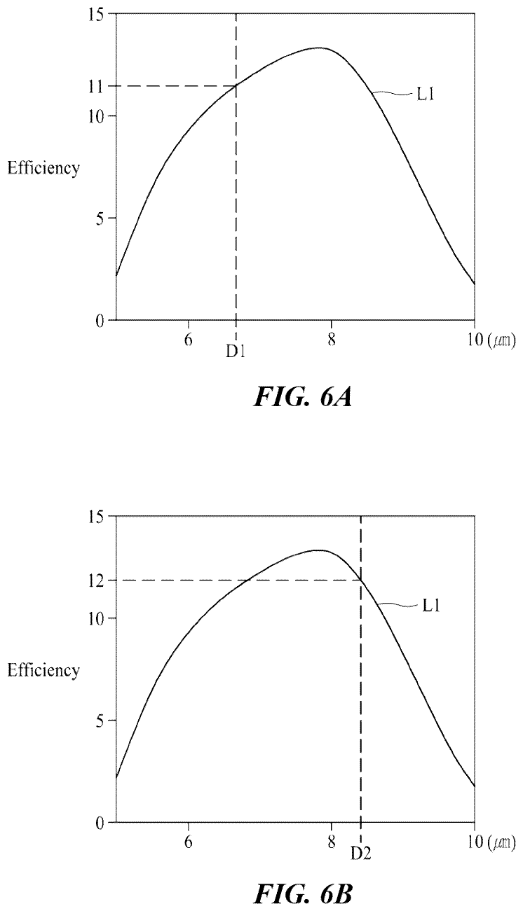

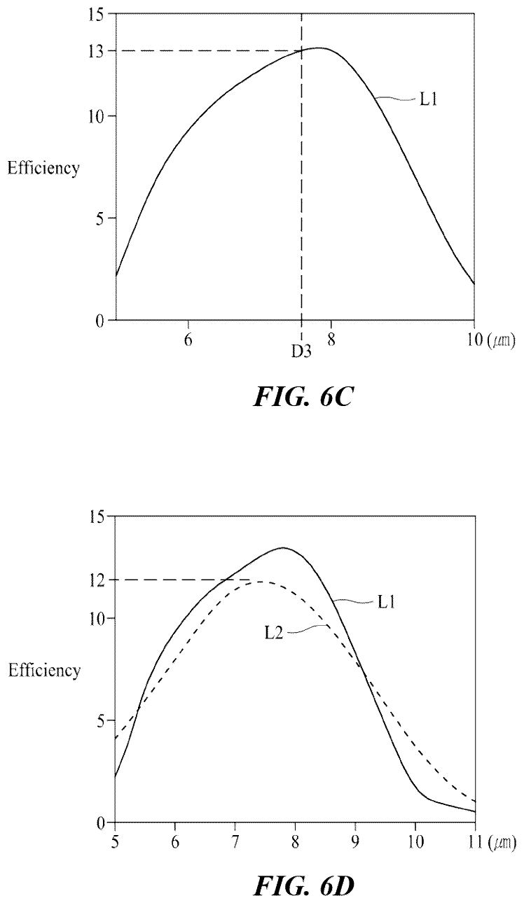

Referring again to FIGS. 2 and 3, in the display apparatus 100 according to one embodiment of the present disclosure, the pixel electrode 114 may include a main body 114a and a plurality of protrusions 114b protruding from the main body 114a toward the reflective portion 130. The plurality of protrusions 114b are used to reduce light extraction efficiency deviation when the separation distance between the pixel electrode 114 and the reflective portion 130 is outside a certain range (or design value) due to process deviation. This will be described in detail with reference to FIGS. 5 to 6D after explaining the structure of the sub-pixel SP of the display apparatus 100.

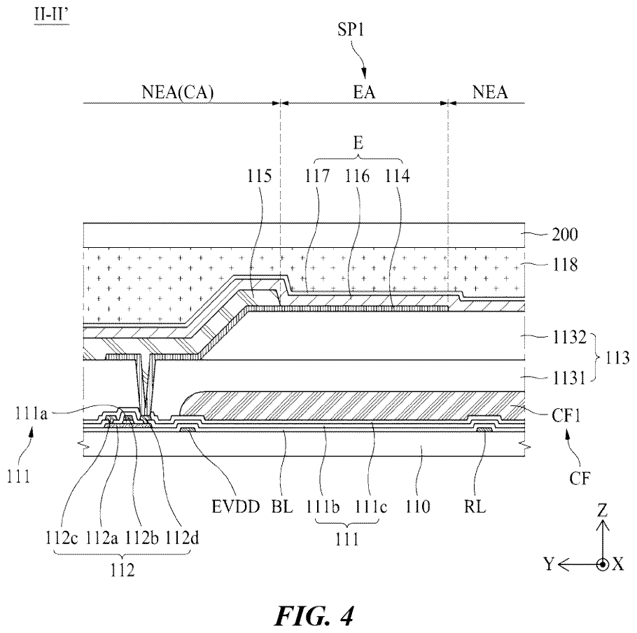

Hereinafter, referring to FIG. 4, a structure of each of the plurality of subpixels SP will be described in detail.

FIG. 4 is a schematic cross-sectional view of the line II-II′ shown in FIG. 2.

Referring to FIG. 4, the display apparatus 100 according to one embodiment of the present disclosure may further include a buffer layer BL, a circuit element layer 111, a thin film transistor 112, an overcoat layer 113, a pixel electrode 114, a bank 115, an organic light emitting layer 116, a reflective electrode 117, an encapsulation layer 118 and a color filter CF.

In more detail, each of the subpixels SP according to one embodiment may include a circuit element layer 111 provided on an upper surface of a buffer layer BL, including a gate insulating layer 111a, an interlayer insulating layer 111b and a passivation layer 111c, an overcoat layer 113 provided on the circuit element layer 111, a pixel electrode 114 provided on the overcoat layer 113, a bank 115 covering an edge of the pixel electrode 114, an organic light emitting layer 116 on the pixel electrode 114 and the bank 115, a reflective electrode 117 on the organic light emitting layer 116, and an encapsulation layer 118 on the reflective electrode 117.

The thin film transistor 112 for driving the subpixel SP may be disposed on the circuit element layer 111. The circuit element layer 111 may be expressed as the term of an inorganic film layer. The buffer layer BL may be included in the circuit element layer 111 together with the gate insulating layer 111a, the interlayer insulating layer 111b and the passivation layer 111c. The pixel electrode 114, the organic light emitting layer 116 and the reflective electrode 117 may be included in the light emitting element layer E.

The buffer layer BL may be formed between the substrate 110 and the gate insulating layer 111a to protect the thin film transistor 112. The buffer layer BL may be disposed on the entire surface (or front surface) of the substrate 110. The pixel power line EVDD for pixel driving may be disposed between the buffer layer BL and the substrate 110. The pixel power line EVDD may be disposed below the bank 115 while being spaced apart from the thin film transistor 112. The reference line RL may also be disposed between the buffer layer BL and the substrate 110. The reference line RL may be disposed in the non-light emission area NEA that does not overlap with the light emission area EA. The buffer layer BL may serve to block diffusion of a material contained in the substrate 110 into a transistor layer during a high temperature process of a manufacturing process of the thin film transistor. Optionally, the buffer layer BL may be omitted in some cases.

The thin film transistor 112 (or a drive transistor) according to an example may include an active layer 112a, a gate electrode 112b, a source electrode 112c, and a drain electrode 112d.

The active layer 112a may include a channel area, a drain area and a source area, which are formed in a thin film transistor area of a circuit area of the subpixel SP. The drain area and the source area may be spaced apart from each other with the channel area interposed therebetween.

The active layer 112a may be formed of a semiconductor material based on any one of amorphous silicon, polycrystalline silicon, oxide and organic material.

The gate insulating layer 111a may be formed on the channel area of the active layer 112a. As an example, the gate insulating layer 111a may be formed in an island shape only on the channel area of the active layer 112a, or may be formed on an entire front surface of the substrate 110 or the buffer layer BL, which includes the active layer 112a.

The gate electrode 112b may be formed on the gate insulating layer 111a to overlap the channel area of the active layer 112a.

The interlayer insulating layer 111b may be formed on the gate electrode 112b and the drain area and the source area of the active layer 112a. As in FIG. 5, the interlayer insulating layer 111b may be formed in the circuit area and an entire light emission area, in which light is emitted to the subpixel SP. However, embodiments of the present disclosure are not limited thereto, the interlayer insulating layer 111b may be patterned between the drain electrode 112d and the gate electrode 112b and drain region of the active layer 112a and may be arranged in an island shape, and moreover, may be patterned between the source electrode 112c and the gate electrode 112b and source region of the active layer 112a and may be arranged in an island shape.

The source electrode 112c may be electrically connected to the source area of the active layer 112a through a source contact hole provided in the interlayer insulating layer 111b overlapped with the source area of the active layer 112a. The drain electrode 112d may be electrically connected to the drain area of the active layer 112a through a drain contact hole provided in the interlayer insulating layer 111b overlapped with the drain area of the active layer 112a.

The drain electrode 112d and the source electrode 112c may be made of the same metal material. For example, each of the drain electrode 112d and the source electrode 112c may be made of a single metal layer, a single layer of an alloy or a multi-layer of two or more layers, which is the same as or different from that of the gate electrode.

In addition, the circuit area may further include first and second switching thin film transistors disposed together with the thin film transistor 112, and a capacitor. Since each of the first and second switching thin film transistors is provided on the circuit area of the subpixel SP to have the same structure as that of the thin film transistor 112, its description will be omitted. The capacitor (not shown) may be provided in an overlap area between the gate electrode 112b and the source electrode 112c of the thin film transistor 112, which overlap each other with the interlayer insulating layer 111b interposed therebetween.

Additionally, in order to prevent a threshold voltage of the thin film transistor provided in a pixel area from being shifted by light, the display panel or the substrate 110 may further include a light shielding layer (not shown) provided below the active layer 112a of at least one of the thin film transistor 112, the first switching thin film transistor or the second switching thin film transistor. The light shielding layer may be disposed between the substrate 110 and the active layer 112a to shield light incident on the active layer 112a through the substrate 110, thereby minimizing a change in the threshold voltage of the transistor due to external light. Also, since the light shielding layer is provided between the substrate 110 and the active layer 112a, the thin film transistor may be prevented from being seen by a user.

The passivation layer 111c may be provided on the substrate 110 to cover the pixel area. The passivation layer 111c covers a drain electrode 112d, a source electrode 112c and a gate electrode 112b of the thin film transistor 112, and the buffer layer BL.

On the other hand, the display apparatus 100 according to one embodiment of the present disclosure may be provided that the bank 115 is disposed only on one side of the light emission area EA in which the circuit area CA is disposed. Accordingly, as shown in FIG. 5, the pixel power line EVDD may be disposed to overlap the bank 115 in the third direction (Z-axis direction), and the reference line RL may not overlap the bank 115 in the third direction (Z-axis direction). The passivation layer 111c may be formed over the circuit area and the light emission area. The passivation layer 111c may be omitted. The color filter CF may be disposed on the passivation layer 111c.

The overcoat layer 113 may be provided on the substrate 110 to cover the passivation layer 111c and the color filter CF. The overcoat layer 113 according to one example may be disposed between the substrate 110 and the pixel electrode 114. When the passivation layer 111c is omitted, the overcoat layer 113 may be provided on the substrate 110 to cover the circuit area. The overcoat layer 113 may be formed in the circuit area CA in which the thin film transistor 112 is disposed and the light emission area EA. In addition, the overcoat layer 113 may be formed in the other non-display area NDA except a pad area PA of the non-display area NDA and the entire display area DA. For example, the overcoat layer 113 may include an extension portion (or an enlarged portion) extended or enlarged from the display area DA to the other non-display area NDA except the pad area PA. Therefore, the overcoat layer 113 may have a size relatively wider than that of the display area DA.

The overcoat layer 113 according to one example may be formed to have a relatively thick thickness, thereby providing a flat surface on the display area DA and the non-display area NDA. For example, the overcoat layer 113 may be made of an organic material such as photo acryl, benzocyclobutene, polyimide and fluorine resin.

The overcoat layer 113 may include a first layer 1131 and a second layer 1132 disposed on the first layer 1131. The first layer 1131 may be disposed on the substrate 110. The second layer 1132 may be disposed between the first layer 1131 and the pixel electrode 114.

As shown in FIG. 3, since the first layer 1131 is provided to cover the passivation layer 111c and the color filter CF, it can be formed continuously across a plurality of subpixels SP. In contrast, as the pattern portion 120 is formed between the plurality of subpixels SP, the second layer 1132 may be formed discontinuously. Therefore, as shown in FIG. 3, a plurality of second layers 1132 may be provided in an island shape on the first layer 1131. Each of the plurality of second layers 1132 may be disposed only in each of the plurality of subpixels SP. Since each of the plurality of second layers 1132 is provided in an island shape, the depth of the pattern portion 120 can be increased compared to the case where the second layers 1132 are connected to each other. In this case, the reflective area of the reflective portion 130 disposed on the pattern portion 120 may be increased, and thus the light extraction efficiency of the display apparatus 100 according to one embodiment of the present disclosure may be improved. However, the present disclosure is not limited to this, and the plurality of second layers 1132 may be connected to each other depending on the depth at which the pattern portion 120 is formed. In this case, since the etching material for forming the pattern portion 120 does not affect the circuit portion (or thin film transistor), damage to the circuit portion (or thin film transistor) can be prevented, and thus a decrease in reliability of the display apparatus 100 according to one embodiment of the present disclosure can be prevented.

In the apparatus 100 according to one embodiment of the present disclosure, a refractive index of the first layer 1131 may be equal to a refractive index of the second layer 1132. If the first layer 1131 and the second layer 1132 have the same refractive index, total reflection does not occur at the interface between the first layer 1131 and the second layer 1132, so front light extraction efficiency can be improved. However, it is not limited to this, and the refractive index of the first layer 1131 may be different from the refractive index of the second layer 1132.

Referring to FIGS. 3 and 4, the upper surface 113a of the second layer 1132 included in the overcoat layer 113 is provided flat, so that the pixel electrode 114 on the overcoat layer 113 can also be provided flat. Additionally, the organic light emitting layer 116 and the reflective electrode 117 formed on the pixel electrode 114 may also be provided in a flat shape. Since the pixel electrode 114, the organic light emitting layer 116, the reflective electrode 117, that is, the light emitting element layer E is provided to be flat in the light emission area EA, a thickness of each of the pixel electrode 114, the organic light emitting layer 116 and the reflective electrode 117 in the light emission area EA may be uniformly formed. Therefore, the organic light emitting layer 116 may be uniformly emitted without deviation in the light emission area EA.

Meanwhile, the pattern portion 120 may be formed by patterning and removing a portion of the overcoat layer 113 (or the second layer 1132 and/or the first layer 1131). The pattern portion 120 according to an example may be formed on the overcoat layer 113 through a photo process using a mask with an opening, and a pattern (or etching) or ashing process after the photo process. After the pattern portion 120 is formed, the pixel electrode 114 is patterned for each subpixel SP on the overcoat layer 113 (or the second layer 1132), and then the organic light emitting layer 116 and the reflective electrode 117 may be formed on the entire surface.

When the pixel electrode 114 is patterned on the overcoat layer 113, the plurality of protrusions 114b may be provided on the pixel electrode 114. For example, the mask used to pattern the pixel electrode 114 may be provided to include an opening having the same shape as the main body 114a and the plurality of protrusions 114b. Through a photo process using such a mask and an etching process, the pixel electrode 114 may be provided in a form including the plurality of protrusions 114b. For example, as shown in the plan view of FIG. 2, the plurality of protrusions 114b may be formed on each of both side (or right and left) of the pixel electrode 114.

Referring back to FIG. 3, the color filter CF may be provided between the substrate 110 (or passivation layer 111c) and the overcoat layer 113. Therefore, the color filter CF may be disposed between the pixel power line, for example, the reference line RL and the reflective portion 130 or between the reference line RL and the pattern portion 120. The color filter CF may include a red color filter (or a first color filter) CF1 for converting white light emitted from the organic light emitting layer 116 into red light, a blue color filter (or a second color filter) CF2 for converting white light into blue light, and a green color filter (or a third color filter) (not shown) for converting white light into green light. The second subpixel SP2, which is a white subpixel, may not include a color filter since the organic light emitting layer 116 emits white light.

The pixel electrode 114 of the subpixel SP may be formed on the overcoat layer 113 (or the second layer 1132). The pixel electrode 114 may be connected to a drain electrode or a source electrode of the thin film transistor 112 through a contact hole passing through the overcoat layer 113 (the first layer 1131) and the passivation layer 111c. One edge of the pixel electrode 114 may be covered by the bank 115. Here, one edge of the pixel electrode 114 is connected to the thin film transistor 112. In other words, one edge of the pixel electrode 114 may mean the pixel electrode 114 disposed in the circuit area CA. The pixel electrode 114 may be made of at least one of a transparent metal material or a semi-transmissive metal material.

Because the display apparatus 100 according to an embodiment of the present disclosure is configured as the bottom emission type, the pixel electrode 114 may be formed of a transparent conductive material (or TCO), such as indium tin oxide (ITO) or indium zinc oxide (IZO) capable of transmitting light, or a semi-transmissive conductive material such as magnesium (Mg), silver (Ag), or an alloy of Mg and Ag.

Meanwhile, the material constituting the pixel electrode 114 may include MoTi. The pixel electrode 114 may be a first electrode or an anode electrode.

The bank 115 is a non-light emission area, which may be disposed on one side of the light emission area EA of each of the plurality of subpixels SP. For example, the bank 115 may be disposed in the non-light emission area NEA where the circuit area CA is located. As shown in FIG. 4, the bank 115 may be formed to cover the portion where an edge of each of the pixel electrodes 114 of each of the subpixels SP connects to the thin film transistor 112. That is, the bank 115 may partially cover the pixel electrodes 114. Accordingly, the bank 115 may prevent the pixel electrode 114 and the reflective electrode 117 from contacting in the circuit area CA. The exposed portion of the pixel electrode 114 that is not covered by the bank 115 may include a light emitting portion (or the light emission area EA).

As described above, the bank 115 is disposed in the non-light emission area NEA in which the circuit area CA is disposed, so that the non-light emission area NEA on the left and the non-light emission area NEA on the right may be asymmetrically provided with respect to the light emission area EA of FIG. 4. For example, based on the light emission area EA of FIG. 4, the left non-light emission area NEA may be provided as a structure including the thin film transistor 112 and the bank 115, and the right non-light emission area NEA may be provided as a structure without the bank 115 on the second layer 1132.

After the bank 115 is formed, an organic light emitting layer 116 may be formed to cover the pixel electrodes 114 and the bank 115. Thus, the bank 115 may be partially provided between the pixel electrodes 114 and the organic light emitting layer 116. The bank 115 may be expressed in terms of a pixel-defining membrane. The bank 115 according to one example may comprise organic material and/or inorganic material. The banks 115 according to one example may be concave or inclined along the profile of the pattern portion 120.

The organic light emitting layer 116 may be formed on the pixel electrodes 114 and the bank 115. According to one example, the organic light emitting layer 116 may be disposed in the light emission area EA and the non-light emission area NEA. The organic light emitting layer 116 may be provided between the pixel electrode 114 and the reflective electrode 117. Thus, when a voltage is applied to each of the pixel electrode 114 and the reflective electrode 117, an electric field is formed between the pixel electrode 114 and the reflective electrode 117. Therefore, the organic light emitting layer 116 may emit light. The organic light emitting layer 116 may be formed of a plurality of subpixels SP and a common layer provided on the bank 115.

The organic light emitting layer 116 according to an embodiment may be provided to emit white light. The organic light emitting layer 116 may include a plurality of stacks which emit lights of different colors. For example, the organic light emitting layer 116 may include a first stack, a second stack, and a charge generating layer (CGL) provided between the first stack and the second stack. The light emitting layer may be provided to emit the white light, and thus, each of the plurality of subpixels SP may include a color filter CF suitable for a corresponding color.

The first stack may be provided on the pixel electrode 114 and may be implemented a structure where a hole injection layer (HIL), a hole transport layer (HTL), a blue emission layer (EML(B)), and an electron transport layer (ETL) are sequentially stacked.

The charge generating layer may supply an electric charge to the first stack and the second stack. The charge generating layer may include an N-type charge generating layer for supplying an electron to the first stack and a P-type charge generating layer for supplying a hole to the second stack. The N-type charge generating layer may include a metal material as a dopant.

The second stack may be provided on the first stack and may be implemented in a structure where a hole transport layer (HTL), a yellow-green (YG) emission layer (EML(YG)), and an electron injection layer (EIL) are sequentially stacked.

In the display apparatus 100 according to an embodiment of the present disclosure, because the organic light emitting layer 116 is provided as a common layer, the first stack, the charge generating layer, and the second stack may be arranged all over the plurality of subpixels SP. The organic light emitting layer 116, according to another example, may be provided in a three-stacked structure or a four-stacked structure, depending on the number of stacks stacked.

The reflective electrode 117 may be formed on the organic light emitting layer 116. The reflective electrodes 117 may be disposed in the light emission area EA and the non-light emission area NEA. The reflective electrode 117 according to one example may include a metal material. The reflective electrode 117 may reflect the light emitted from the organic light emitting layer 116 in the plurality of subpixels SP toward the lower surface of the substrate 110. Therefore, the display apparatus 100 according to one embodiment of the present disclosure may be implemented as a bottom emission type display apparatus.

The display apparatus 100 according to one embodiment of the present disclosure is a bottom emission type and has to reflect light emitted from the light emitting layer 116 toward the substrate 110, and thus the reflective electrode 117 may be made of a metal material having high reflectance. The reflective electrode 117 according to one example may be formed of a metal material having high reflectance such as a stacked structure (Ti/Al/Ti) of aluminum and titanium, a stacked structure (ITO/Al/ITO) of aluminum and ITO, an Ag alloy and a stacked structure (ITO/Ag alloy/ITO) of Ag alloy and ITO. The Ag alloy may be an alloy such as silver (Ag), palladium (Pd) and copper (Cu). The reflective electrode 117 may be expressed as terms such as a second electrode, a cathode electrode and a counter electrode.

On the other hand, in the display apparatus 100 according to one embodiment of the present disclosure, the reflective portion 130 may be a part of the reflective electrode 117. Thus, the reflective portion 130 may reflect light, which is directed toward the adjacent sub-pixel SP, toward the light emission area EA or the non-light emission area NEA of the emitting sub-pixel SP. The reflective portion 130 is a portion of the reflective electrode 117, and may be denoted by the drawing symbol 117a, as shown in FIG. 3. The reflective portion 130 may refer to a reflective electrode 117 that overlaps the pattern portion 120 (or the non-light emission area NEA). In one example, the reflective portion 130 may include a reflective electrode that is inclined while overlaps the pattern portion 120 and a reflective electrode that is flat while overlaps the pattern portion 120.

The encapsulation layer 118 is formed on the reflective electrode 117. The encapsulation layer 118 serves to prevent oxygen or moisture from being permeated into the organic light emitting layer 116 and the reflective electrode 117. To this end, the encapsulation layer 118 may include at least one inorganic film and at least one organic film. The encapsulation layer 118 may be disposed not only in the light emission area EA but also in the non-light emission area NEA. The encapsulation layer 118 may be disposed between the reflective electrode 117 and an opposing substrate 200.

Referring to FIG. 3, the display apparatus 100 according to one embodiment of the present disclosure may be provided in a bankless structure with no banks between the plurality of subpixels SP (for example, between the first subpixel SP1 and the second subpixel SP2). Accordingly, the organic light emitting layer 116 may have a structural characteristic of being in contact with the upper surface 1132a of the second layer 1132 adjacent to the end of the pixel electrode 114. However, the present disclosure is not limited thereto, and the display apparatus 100 according to one embodiment of the present disclosure may include a bank covering an edge of the pixel electrode 114 shown in FIG. 3. However, when a bank is included, the width of the non-light emission area NEA increases due to the bank, so it may be suitable for implementing a low-resolution display apparatus. On the other hand, in the case of the display apparatus 100 having a bankless structure, the width of the non-light emission area NEA is narrower than that of the display apparatus with banks, so it may be more suitable for implementing a high-resolution display apparatus.

Meanwhile, when the display apparatus 100 according to one embodiment of the present disclosure is provided in a bankless structure, since there is no bank, the width of the light emission area EA may be equal to a width PW of the pixel electrode 114. In addition, when the display apparatus 100 according to one embodiment of the present disclosure is provided in a bankless structure, since there is no bank, a width of the non-light emission area NEA may be equal to a width NW between the pixel electrodes 114 included in each of the plurality of subpixels SP.

Hereinafter, with reference to FIGS. 3 to 6D, the pixel electrode 114 and the reflective portion 130 included in the display apparatus 100 according to one embodiment of the present disclosure will be described in detail.

FIG. 5 is a schematic plan view showing a pixel electrode and a reflective portion of one sub-pixel shown in FIG. 2, FIG. 6A is a graph showing light extraction efficiency at D1 in FIG. 5, FIG. 6B is a graph showing light extraction efficiency at D2 in FIG. 5, FIG. 6C is a graph showing light extraction efficiency at D3 in FIG. 5, and FIG. 6D is a graph showing the light extraction efficiency of a display apparatus according to one embodiment of the present disclosure and the light extraction efficiency of a display apparatus according to a comparative example.

Referring to FIG. 5, the pixel electrode 114 may include a main body 114a and a plurality of protrusions 114b.

The main body 114a according to one example may be arranged to overlap the center area of the light emission area EA. The main body 114a according to one example may be provided in a square shape on a plan view. Based on FIG. 5, the plurality of protrusions 114b may be provided adjacent to each other in the second direction (Y-axis direction) on each of the right and left sides of the main body 114a.

As shown in FIG. 5, each of the plurality of protrusions 114b protrudes in the first direction (X-axis direction) toward the reflective portion 130 and may be disposed on the right side and left side of the main body 114a, respectively. Each of the plurality of protrusions 114b may be disposed between the main body 114a and the reflective portion 130. Each of the plurality of protrusions 114b according to an example may be arranged to be spaced apart from the reflective portion 130 at a first distance D1. Here, the first distance D1 may be the distance from the end of the protrusion 114b to the end of the reflective portion 130. The end of the reflective portion 130 refers to the horizontal distance to the point Q where the end of the second layer 1132 (or the inclined surface 1132b of the second layer 1132) and the bottom surface 120b of the pattern portion 120 meet with respect to FIG. 3. Here, the horizontal distance may be parallel to the first direction (X-axis direction).

Each of the plurality of protrusions 114b may be provided in a triangular shape, as shown in FIG. 5, but is not limited thereto, and may be provided in a trapezoidal shape and/or a curved shape as long as the shape can reduce the deviation in light extraction efficiency. As a result, each of the plurality of protrusions 114b may be formed in at least one of a triangular shape, a trapezoidal shape, and a curved shape.

The main body 114a may be disposed to be spaced apart from the reflective portion 130 at a second distance D2 that is different from the first distance D1. For example, the main body 114a may be arranged to be spaced apart from the reflective portion 130 at a second distance D2 that is longer than the first distance D1. Since the plurality of protrusions 114b are disposed between the main body 114a and the reflective portion 130, the main body 114a may be arranged to be spaced further apart from the reflective portion 130 than the plurality of protrusions 114b.

As shown in FIG. 5, the display apparatus 100 according to one embodiment of the present disclosure has a plurality of protrusions 114b (or ends of the protrusions 114b) spaced apart from the reflective portion 130 at a first distance D1, and the main body 114a is arranged to be spaced apart from the reflective portion 130 at the second distance D2 that is different from the first distance D1. Therefore, a first light extraction efficiency of the reflective portion 130 adjacent to the plurality of protrusions 114b may be different from a second light extraction efficiency of the reflective portion 130 adjacent to the main body 114a. For example, the first light extraction efficiency may be higher than the second light extraction efficiency, or vice versa.

Accordingly, in the display apparatus 100 according to one embodiment of the present disclosure, the separation distance between the pixel electrode 114 and the reflective portion 130 may be within a certain range (or design value) due to the plurality of protrusions 114b provided on one side (right side or left side with respect to FIG. 5) of the pixel electrode 114 (or main body 114a). Therefore, in display apparatus 100 according to one embodiment of the present disclosure, even if a process deviation occurs when forming the pixel electrode 114, the deviation in light extraction efficiency can be reduced compared to the case of a general display apparatus in which both sides of the pixel electrode facing the reflective portion are provided in a straight shape.

For example, in the display apparatus 100 according to one embodiment of the present disclosure, when the separation distance between the pixel electrode 114 and the reflector 130 has a normal distribution centered on the optimal design value (e.g., 8 μm), it is assumed that the tolerance of 95% of the separation distance distribution falls within +4.3 μm or −4.3 μm. Here, when ΔD_{f} (shown in FIG. 5) is designed to be 3 μm, the light extraction efficiency graph (e.g., L2 in FIG. 6D) according to the separation distance of the display apparatus 100 provided with the pixel electrode 114 having the uneven structure (or the plurality of protrusions 114b) of the present disclosure may be similar to a graph obtained by moving the average of the light extraction efficiency graph (e.g., L1 in FIG. 6D) according to the separation distance of a general display apparatus in which both sides of the pixel electrode are provided in a straight shape by about 3 μm. Therefore, the display apparatus 100 according to one embodiment of the present disclosure may have a graph pattern such as L2 in which the minimum light extraction efficiency value is larger and the maximum light extraction efficiency value is smaller compared to the light extraction efficiency graph (e.g., L1 in FIG. 6D) of a general display apparatus in which both sides of the pixel electrode facing the reflective portion are provided in a straight shape. Therefore, in the display apparatus 100 according to one embodiment of the present disclosure, the deviation in light extraction efficiency can be reduced. Meanwhile, since the minimum light extraction efficiency has a greater influence on the panel luminance of a display apparatus than the maximum light extraction efficiency, the larger the deviation of the minimum light extraction efficiency, the lower the overall panel performance may be. Accordingly, the display apparatus 100 according to one embodiment of the present disclosure has a higher minimum light extraction efficiency than a general display apparatus, and thus overall panel performance degradation can be prevented and panel luminance can be improved.

The ΔD_{f} may mean a distance that is the sum of the protruding distance and the recessed distance of the pixel electrode 114 around the virtual reference line ML connecting the midpoints MP of each of the plurality of protrusions 114b. The midpoint MP may mean a point that is half of the maximum protrusion length of each of the plurality of protrusions 114b protruding in the first direction (X-axis direction) toward the reflective portion 130. The protruding portion of the pixel electrode 114 may be a part of each of the plurality of protrusions 114b, and the recessed portion of the pixel electrode 114 may be a portion of each of a plurality of recesses RP. The plurality of recesses RP may be disposed between the plurality of protrusions 114b.

Each of the plurality of recesses RP may be provided in a shape inverted from that of each of the plurality of protrusions 114b. If the shapes of the plurality of protrusions 114b and the plurality of recesses RP are different, this may mean that the separation distance between each of the plurality of protrusions 114b (or each of the plurality of recesses RP) and the reflective portion 130 is non-uniform, which may actually increase the standard deviation of light extraction efficiency. Therefore, in display apparatus 100 according to one embodiment of the present disclosure, each of the plurality of recesses RP is provided in a shape that is inverted from the shape of each of the plurality of protrusions 114b, so that the separation distance between each of the plurality of protrusions 114b (or each of the plurality of recesses RP) and the reflective portion 130 can be provided uniformly, thereby preventing an increase in the standard deviation of light extraction efficiency.

Referring to FIG. 5, at a position where the protrusion 114b and the reflective portion 130 are spaced apart by a first distance D1, the pixel electrode 114 may protrude further toward the reflective portion 130 beyond the virtual reference line ML with respect to the main body 114a. In contrast, at a position where the protrusion 114b and the reflective portion 130 are spaced apart by a second distance D2, the pixel electrode 114 may be recessed toward the main body 114a beyond the virtual reference line ML with respect to the reflective portion 130. Therefore, as shown in FIG. 5, each of the plurality of protrusions 114b protrudes from the main body 114a beyond the virtual reference line ML toward the reflective portion 130, and each of the plurality of recesses RP may have a structural feature of being recessed toward the main body 114a rather than the virtual reference line ML.

Meanwhile, since ΔD_{f} is equal to the sum of the protruding distance and the recessed distance of the pixel electrode 114 around the virtual reference line ML, each of the plurality of protrusions 114b may be equal to the maximum protruding distance PD protruding in the first direction (X-axis direction) from the main body 114a toward the reflective portion 130.

As a result, the display apparatus 100 according to one embodiment of the present disclosure is provided with the plurality of protrusions 114b on both sides of the pixel electrode 114 facing the reflective portion 130, so that the pixel electrode 114 can be provided in a structure having an uneven shape (or wave shape) on both sides as a whole, and even if process deviation occurs as a result, deviation in light extraction efficiency may be minimized.

Hereinafter, in conjunction with FIGS. 5 and 6A to 6D, the light extraction efficiency of the display apparatus 100 according to one embodiment of the present disclosure and a general display apparatus provided in a straight form without protrusions on both sides of the pixel electrode will be compared and explained.

As shown in FIG. 5, in the display apparatus 100 according to one embodiment of the present disclosure, the pixel electrode 114 may include the main body 114a and the plurality of protrusions 114b. Accordingly, the ends of the plurality of protrusions 114b and the reflective portion 130 may be separated by a first distance D1, the main body 114a and the reflective portion 130 may be separated by a second distance D2, and the midpoint MP and the reflective portion 130 may be separated by a third distance D3. Since the light extraction efficiency of the reflective portion 130 is largely due to the light emitted from the edge of the pixel electrode 114 and directed toward the reflective portion 130, the third distance D3 may be the shortest distance from the point (or the inclined surface of the protrusion 114b) where the edge of the protrusion 114b and the virtual reference line ML intersect to the reflective portion 130. As shown in FIG. 5, the third distance D3 may be shorter than the second distance D2 and longer than the first distance D1.

Referring to FIG. 6A, the horizontal axis represents the separation distance between the pixel electrode and the reflective portion, and the vertical axis represents light extraction efficiency. In the case of a general display apparatus, since it has a straight shape without a plurality of protrusions between the pixel electrode and the reflective portion, it can have a graph of light extraction efficiency such as L1 depending on the separation distance between the pixel electrode and the reflective portion. As shown in FIG. 6A, in the case of a general display apparatus, when the separation distance between the pixel electrode and the reflective portion is about 10 μm, it can have a light extraction efficiency of 2, which is the minimum value. Additionally, a general display apparatus may have a pattern graph that slopes upward to the right as the distance between the pixel electrode and the reflective portion increases, has a light extraction efficiency of 13.5, which reaches its maximum value at a distance of about 8 μm, and slopes downward to the right. In summary, a general display apparatus can have a light extraction efficiency of about 2 to about 13.5 when the separation distance between the pixel electrode and the reflective portion is 0 to 10 μm.

On the other hand, as shown in FIG. 6A, the display apparatus 100 according to one embodiment of the present disclosure has a light extraction efficiency of about 11 when the first distance D1, which is the shortest separation distance between the protrusion 114b and the reflective portion 130, is about 6.7 μm. And, as shown in FIG. 6B, the display apparatus 100 according to one embodiment of the present disclosure may have a light extraction efficiency of about 12 when the second distance D2 between the main body 114a and the reflective portion 130 is about 8.3 μm. In addition, as shown in FIG. 6C, the display apparatus 100 according to one embodiment of the present disclosure has a light extraction efficiency of about 13 when the third distance D3 between the inclined surface of the protrusion 114b and the reflective portion 130 is about 7.6 μm.

Summarizing these simulation results, as shown in FIG. 6D, the display apparatus 100 according to one embodiment of the present disclosure may have the form of a graph of L2 having a light extraction efficiency of about 4 to about 12 when the separation distance between the pixel electrode 114 including a plurality of protrusions 114b and the main body 114a, and the reflective portion 130 is 0 to 10 μm. Here, the synthesis of the simulation results may mean the average efficiency value of light extraction efficiency according to the separation distance. Accordingly, the light extraction efficiency at the third distance D3 in FIG. 6C is about 13, but the maximum light extraction efficiency in FIG. 6D may be lowered to about 12. As a result, the display apparatus 100 according to one embodiment of the present disclosure may have a higher minimum light extraction efficiency value and a smaller standard deviation value for the maximum light extraction efficiency value than a general display apparatus without a plurality of protrusions on the pixel electrode.

As a result, the display apparatus 100 according to one embodiment of the present disclosure is provided so that the pixel electrode 114 includes a plurality of protrusions 114b, so that even if a process deviation occurs when forming the pixel electrode, the distance between the pixel electrode 114 and the reflective portion 130 can be limited to fall within a certain range (or design value), and thus the light extraction efficiency deviation may be reduced or alleviated. That is, in the display apparatus 100 according to one embodiment of the present disclosure, the plurality of protrusions 114b may be a structure that has a buffer function for the designed separation distance between the pixel electrode 114 and the reflective portion 130. Therefore, in the display apparatus 100 according to one embodiment of the present disclosure, the level of light extraction efficiency deviation due to process deviation may be reduced compared to a general display apparatus, and thus robustness to process deviation may be improved.

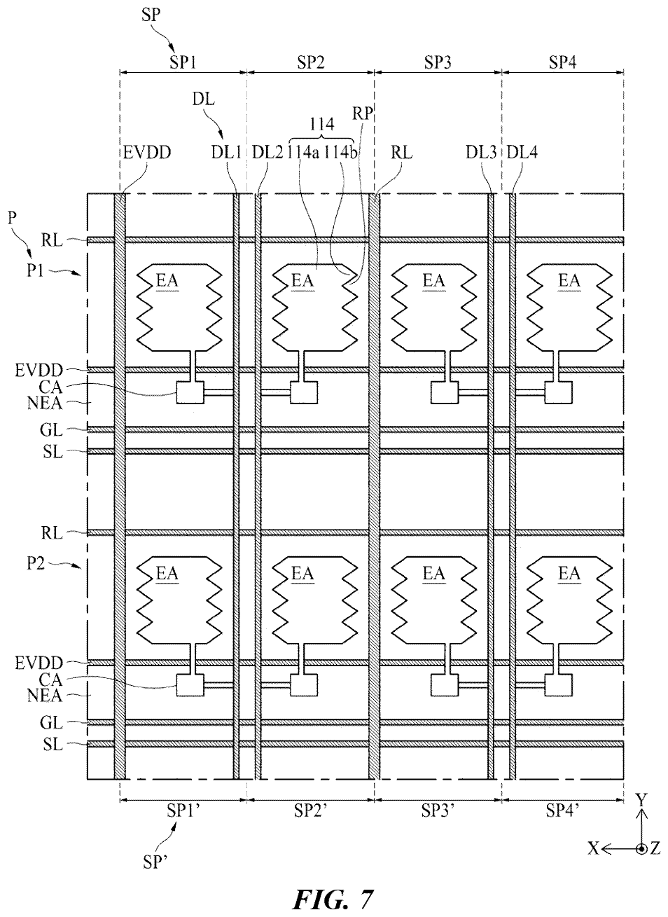

FIG. 7 is a schematic plan view showing a plurality of pixels of a display apparatus according to one embodiment of the present disclosure.

Referring to FIG. 7, the plurality of protrusions 114b may be disposed between the first subpixel SP1 and the second subpixel SP2 in a second direction (Y-axis direction) that intersects the first direction (X-axis direction). Accordingly, on one side of one pixel electrode 114, the plurality of protrusions 114b may be disposed adjacent to each other in the second direction (Y-axis direction), and the plurality of recesses RP may be disposed between the plurality of protrusions 114b. For example, one recessed portion RP may be disposed between two protrusions 114b disposed in the second direction (Y-axis direction).

Referring again to FIG. 7, the display apparatus 100 according to one embodiment of the present disclosure may include the plurality of pixels P. The plurality of pixels P according to one example may include a first pixel P1 and a second pixel P2 arranged adjacent to each other in the second direction (Y-axis direction). The first pixel P1 may include the first to fourth subpixels SP1, S2, SP3, and SP4 arranged adjacent to each other in the first direction (X-axis direction). The second pixel P2 may include a plurality of subpixels SP′ arranged adjacent to each other in the first direction (X-axis direction). According to one example, the plurality of subpixels SP′ of the second pixel P2 may include other first to fourth subpixels SP1′, S2′, SP3′, and SP4′. Accordingly, the first subpixel SP1 of the first pixel P1 and the other first subpixel SP1′ of the second pixel P2 may be arranged adjacent to each other in the second direction (Y-axis direction) and emit the same color (or first color). Therefore, the display apparatus 100 according to one embodiment of the present disclosure may be provided in a stripe-shaped structure in which a plurality of subpixels SP emitting the same color are arranged adjacent to each other in the second direction (Y-axis direction). However, it is not limited thereto, and the display apparatus 100 according to one embodiment of the present disclosure may be provided with a plurality of subpixels SP emitting different colors arranged adjacent to each other in the second direction (Y-axis direction).

In the display apparatus 100 according to one embodiment of the present disclosure, the plurality of protrusions 114b may not be disposed between the first subpixel SP1 and the other first subpixel SP1′. This is because a plurality of wirings such as the gate line GL and the sensing line SL and the circuit area CA are disposed between the first subpixel SP1 and the other first subpixel SP1′. Not only is it difficult to form the plurality of protrusions 114b between the first subpixel SP1 and the other first subpixel SP1′, but even if it can be formed, the plurality of wirings or circuit areas CA may be damaged by the process, which may reduce reliability. Therefore, the display apparatus 100 according to one embodiment of the present disclosure is provided so that the plurality of protrusions 114b are not disposed between the first subpixel SP1 (or the first pixel P1) and the other first subpixel SP1′ (or the second pixel P2), so that it can be easily manufactured while preventing a decrease in the reliability of the display apparatus.

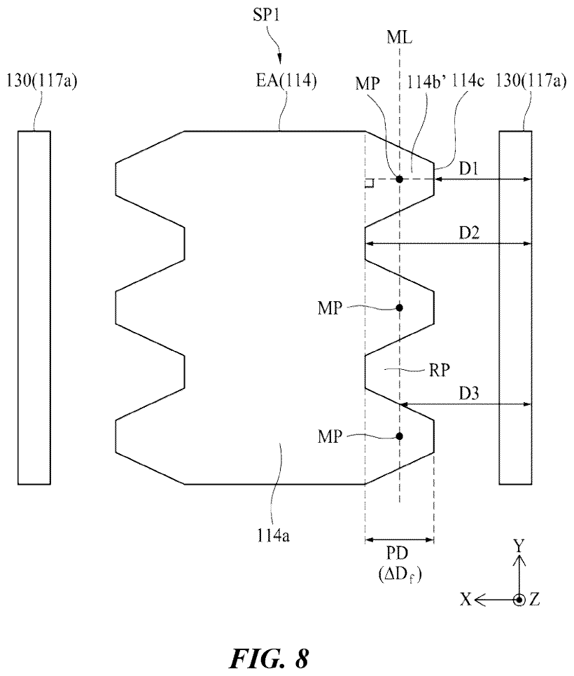

FIG. 8 is a schematic plan view showing a pixel electrode and a reflective portion of one sub-pixel of a display apparatus according to another embodiment of the present disclosure.

Referring to FIG. 8, the display apparatus 100 according to one embodiment of the present disclosure is the same as the display apparatus according to FIG. 1 described above, except that the shape of each of the plurality of protrusions 114b is changed. Accordingly, the same reference numerals are assigned to the same components, and only the different components will be described below.

In the case of the display apparatus according to FIG. 1 described above, each of the plurality of protrusions 114b may be provided in a triangular shape that protrudes from the main body 114a toward the reflective portion 130 in the first direction (X-axis direction). Accordingly, in the case of the display apparatus according to FIG. 1, the ends of each of the plurality of protrusions 114b and the reflective portion 130 may be spaced apart from each other by a first distance D1, which is the shortest distance. However, since the end of the protrusion 114b facing the reflective portion 130 has a sharp spire (or dot) shape, the amount of light emitted toward the reflective portion 130 may be small. In this case, the efficiency of extracting light reflected by the reflective portion 130 and emitted to the substrate 110 may be low.

In contrast, in the case of the display apparatus according to FIG. 8, each of the plurality of protrusions 114b′ may be provided in a trapezoidal shape. Accordingly, in the display apparatus according to FIG. 8, a flat portion 114c may be formed on each of the plurality of protrusions 114b′. The flat portion 114c according to one example may be disposed parallel to the reflective portion 130, but is not limited thereto. Therefore, in the case of the display apparatus according to FIG. 8, even if the end of each of the plurality of protrusions 114b and the reflective portion 130 are separated by the first distance D1, which is the shortest distance, the end of the protrusion 114b facing the reflective portion 130 is in the form of a line (or surface), so the amount of light emitted toward the reflective portion 130 may be large. Therefore, in the case of the display apparatus according to FIG. 8, the efficiency of extracting light reflected by the reflective portion 130 and emitted to the substrate 110 may be high.

Meanwhile, as shown in FIG. 8, in the display apparatus 100 according to another embodiment of the present disclosure, each of the plurality of protrusions 114b′ is provided in a trapezoidal shape, so that each of the plurality of recesses RP disposed between the plurality of protrusions 114′ can be provided in an inverted trapezoidal shape. Therefore, in the display apparatus 100 according to another embodiment of the present disclosure, each of both sides (e.g., the right side and the left side of the pixel electrode 114 with reference to FIG. 8) of the pixel electrode 114 facing the reflective portion 130 is provided to have a uniform uneven shape, thereby preventing an increase in the standard deviation of light extraction efficiency.

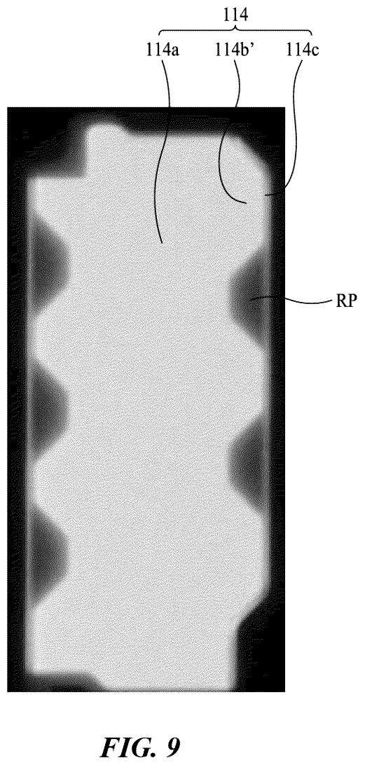

FIG. 9 is a schematic image illustrating light extraction characteristics of a display apparatus according to another embodiment of the present disclosure.

Referring to FIG. 9, it can be seen that a first part (or protruding portion) adjacent to each of the plurality of protrusions 114b′ protruding from the main body 114a has high light brightness, and the second part (or concave portion) adjacent to each of the plurality of recesses RP has low light brightness. The high brightness of light may mean that light extraction efficiency is high, and a low brightness of light may mean that light extraction efficiency is low. Accordingly, the display apparatus 100 according to another embodiment of the present disclosure is provided with a small distance between the pixel electrode 114 and the reflective portion 130 due to a plurality of protrusions 114b′, so that even if a process deviation occurs, the distance at which the pixel electrode 114 is separated from the reflective portion 130 may be limited to a certain range (or design value), and thus, the deviation in light extraction efficiency can be reduced or alleviated.

Meanwhile, as illustrated in FIG. 9, a display apparatus 100 according to another embodiment of the present disclosure is provided such that the pixel electrode 114 further includes the flat portion 114c, so that light extraction efficiency in a portion adjacent to the flat portion 114c can be maximized.

The display apparatus according to the present disclosure is provided to have the reflective portion disposed on the pattern portion that is formed to be concave between the plurality of sub-pixels, so that light directed at the adjacent sub-pixels may be reflected from the reflective portion, thereby improving light extraction efficiency.

Since the display apparatus according to the present disclosure may have light extraction even in the non-light emission area through the reflective portion, it may have the same light extraction efficiency or even better light extraction efficiency with lower power compared to a display apparatus without the reflective portion, thereby reducing overall power consumption.

In the display apparatus according to the present disclosure, the pixel electrode is provided to include the plurality of protrusions protruding from the main body toward the reflective portion, so that variation in light extraction efficiency can be reduced.

The effects to be obtained from the present disclosure are not limited to those mentioned above, and other effects not mentioned will be apparent to one of ordinary skill in the art from the description.

Embodiments of the present disclosure have been described in more detail with reference to the accompanying drawings, but the present disclosure is not necessarily limited to these embodiments and may be practiced in various modifications without departing from the technical ideas of the present disclosure. Accordingly, the embodiments disclosed herein are intended to illustrate, not limit, the technical ideas of the present disclosure, and the scope of the technical ideas of the present disclosure is not limited by these embodiments. Therefore, the embodiments described above are exemplary in all respects and should be understood as non-limiting. All technical ideas within the scope of protection of this specification shall be construed to be included within the scope of the claims of this specification.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a substrate including a plurality of pixels having a plurality of sub-pixels;
a pattern portion on the substrate and concavely formed in a non-light emission area between the plurality of the sub-pixels; and
a reflective portion on the pattern portion,
wherein each of the plurality of subpixels includes a pixel electrode spaced apart from the reflective portion, and
wherein the pixel electrode includes a main body and a plurality of protrusions extending from the main body toward the reflective portion.

2. The display apparatus of claim 1, wherein, in operation, the plurality of protrusions is configured to reduce a deviation in light extraction efficiency arising from a distance variation between the pixel electrode and the reflective portion, and
wherein each of the plurality of protrusions is disposed to face the reflective portion.

3. The display apparatus of claim 1, wherein each of the plurality of protrusions is spaced apart from the reflective portion at a first distance, and
wherein the main body is spaced apart from the reflective portion by a second distance that is longer than the first distance.

4. The display apparatus of claim 1, wherein a first light extraction efficiency of the reflective portion adjacent to the plurality of protrusions is different from a second light extraction efficiency of the reflective portion adjacent to the main body.

5. The display apparatus of claim 1, wherein each of the plurality of protrusions is formed in at least one of a triangular shape, a trapezoidal shape, and a curved shape.

6. The display apparatus of claim 1, further comprising:
a plurality of concave portions between the plurality of protrusions,
wherein each of the plurality of concave portions is provided in a shape reversed from that of each of the plurality of protrusions.

7. The display apparatus of claim 6, wherein each of the plurality of protrusions includes a midpoint that is half the maximum protrusion length protruding toward the reflective portion,
wherein each of the plurality of sub-pixels includes a virtual reference line connecting the midpoints of each of the plurality of protrusions,
wherein each of the plurality of protrusions protrudes from the main body beyond the virtual reference line toward the reflective portion, and
wherein each of the plurality of concave portions is recessed toward the main body rather than the virtual reference line.

8. The display apparatus of claim 1, wherein the plurality of sub-pixels includes:
a first subpixel provided to emit a light of first color; and
a second sub-pixel adjacent to the first sub-pixel in a first direction and configured to emit a light of second color different from the first color,
wherein the plurality of protrusions is disposed in a second direction transverse to the first direction between the first subpixel and the second subpixel.

9. The display apparatus of claim 8, wherein the plurality of subpixels further includes another first subpixel adjacent to the first subpixel in the second direction and configured to emit the light of first color, and
wherein the plurality of protrusions is not disposed between the first subpixel and the another first subpixel.

10. The display apparatus of claim 1, wherein the reflective portion is partially disposed closer to the substrate than the pixel electrode.

11. The display apparatus of claim 1, wherein the plurality of sub-pixels further includes:
an organic light emitting layer on the pixel electrode; and
a reflective electrode on the organic light emitting layer,
wherein the reflective portion is a part of the reflective electrode.

12. The display apparatus of claim 11, wherein the plurality of subpixels further includes an overcoat layer between the substrate and the pixel electrode,
wherein the overcoat layer comprising:
a first layer on the substrate; and
a second layer between the first layer and the pixel electrode.

13. The display apparatus of claim 12, wherein the first layer is disposed continuously across the plurality of subpixels, and
wherein the second layer is formed discontinuously to be disposed in each of the plurality of subpixels.

14. The display apparatus of claim 12, wherein a refractive index of the first layer is equal to a refractive index of the second layer.

15. The display apparatus of claim 12, wherein the second layer includes an upper surface partially in contact with the pixel electrode and an inclined surface connected to the upper surface and disposed to be inclined.

16. The display apparatus of claim 15, wherein the organic light emitting layer is in contact with the upper surface of the second layer adjacent to an end of the pixel electrode.

17. The display apparatus of claim 15, wherein the upper surface of the second layer forms an obtuse angle with the inclined surface of the second layer.

18. The display apparatus of claim 15, wherein the inclined surface of the second layer forms an obtuse angle with the upper surface of the first layer.

19. The display apparatus of claim 1, wherein a width of the pattern portion decreases in a direction from the reflective portion toward the substrate.

20. The display apparatus of claim 1, wherein a width of the non-light emission area is equal to a width between pixel electrodes included in each of the plurality of subpixels.
